(19) United States
(12) Patent Application Publication
(10) Pub. No.: US 2025/0318074 A1
(43) Pub. Date: Oct. 9, 2025

(54) LIQUID COOLING DEVICE

(71) Applicant: Delta Electronics, Inc., Taoyuan City (TW)

(72) Inventors: Shih-Kang Lin, Taoyuan City (TW); Li-Kuang Tan, Taoyuan City (TW); Yi-Tseng Li, Taoyuan City (TW)

(21) Appl. No.: 18/883,164

(22) Filed: Sep. 12, 2024

(30) Foreign Application Priority Data
Apr. 3, 2024 (CN) 202420685673.4

(51) Int. Cl. H05K 7/20; F28F 13/06

(52) U.S. Cl. CPC H05K 7/20254; F28F 13/06; F28F 2215/04

(57) ABSTRACT

A liquid cooling device includes a bottom plate, a cooling fin assembly and a base. The cooling fin assembly is disposed on the bottom plate and includes a plurality of first cooling fins, a plurality of second cooling fins, and a third cooling fin. The third cooling fin is disposed between the first cooling fins and the second cooling fins, and has a first lateral side and a second lateral side, the first lateral side faces the first cooling fins, the second lateral side faces the second cooling fins. The base covers on the cooling fin assembly and the bottom plate and has an inlet and an outlet. The inlet faces a first top of the first cooling fins, and the outlet faces a second top of the second cooling fins.

### CROSS-REFERENCE TO RELATED APPLICATION

This application claims priority to China Patent Application No. 202420685673.4, filed on Apr. 3, 2024. The entire contents of the above-mentioned application are incorporated herein by reference for all purposes.

### FIELD OF THE INVENTION

The present disclosure relates to a liquid cooling device, and more particularly to a liquid cooling device with fast flow and long path, so as to enhance heat exchange efficiency.

### BACKGROUND OF THE INVENTION

With increasing development of science and technology, the efficiency of electronic devices is gradually improved, and the power of the electronic components used for operation inside the electronic devices is also increased. Since the electronic components will generate more heat during operation, the issue of heat dissipation is becoming increasingly important. In order to dissipate heat from electronic components, various heat dissipation devices are arranged around the heat-generating electronic components, so as to prevent the temperature of the electronic components from being too high and affecting the performance and stability of the electronic equipment during operation. For example, attaching a liquid cooling device on the heat-generating electronic component, it can directly exchange heat with the heat source through the circulating flow of the working fluid. Compared with other heat dissipation devices, it can directly and effectively dissipate heat. Accordingly, liquid cooling devices are widely used in electronic devices.

The conventional liquid cooling device 1 is shown as FIG. 1A and FIG. 1B. In the prior art, the liquid cooling device 1 has a bottom plate 10 and a cover 11, and a plurality of cooling fins 12 are disposed on the bottom plate 10. In this prior art, the bottom plate 10 is often attached to the heat-generating electronic components (not shown). As shown in FIG. 1A, the two sides of the cover 11 are respectively communicated with an inlet tube 13 and an outlet tube 14. When the working fluid flows into the liquid cooling device 1 from the inlet tube 13 of the cover 11, as shown by arrow A, it flows from the first ends 12a of the plurality of cooling fins 12 to the second end 12b, and then flows out from the outlet tube 14, so that to exchange heat with the heat-generating electronic components attached under the bottom plate 10, and achieve the purpose of heat dissipation. However, as shown in FIG. 1B, it is cleared that the heat-generating electronic components of zone I adjacent to the inlet tube 13 undergo heat exchange first, so that the heat dissipation efficiency of zone I is better and the temperature drops faster. Since part of the heat is exchanged into the working fluid, the temperature of the working fluid near the outlet tube 14 increases, resulting in lower heat dissipation efficiency in zone II and significantly lower cooling efficiency. Therefore, the liquid cooling device 1 of the prior art cannot achieve a uniform and effective heat dissipation effect.

Moreover, another conventional liquid cooling device 2 is as described in U.S. Pat. No. 8,746,330, which is briefly shown in FIG. 2A and FIG. 2B. As shown in FIG. 2A, the liquid cooling device 2 has a bottom plate 20 and a cover 21, and a plurality of cooling fins 22 are disposed on the bottom plate 20. In this prior art, there is a partition plate 210 disposed between the cover 21 and the cooling fins 22 for separating the space inside the cover 21 into an upper cavity 21a and a lower cavity 21b. Moreover, a long inlet 210a is disposed in the center of the partition plate 210, and two long outlets 210b are disposed in the two opposite side of the partition plate 210. As shown in FIG. 2A, the two sides of the cover 21 are respectively communicated with an inlet tube 23 and an outlet tube 24. When the working fluid flows into the liquid cooling device 2, as shown by arrow B1, it flows from the inlet tube 23 of the cover 21 to the upper cavity 21a, and then flows downward to the lower cavity 21b from the inlet 210a in the center of the partition plate 210, and flows from the center portion 22c of the plurality of cooling fins 22 to the first ends 22a and the second end 22b, as shown by arrow B2, so that to exchange heat with the cooling fins 22, and then flows out from the two outlets 210b disposed in the two sides of the partition plate 210, finally flows out the liquid cooling device 2 through the outlet tube 24. As shown in FIG. 2B, the liquid cooling device 2 can effectively dissipate heat of the heat-generating electronic components attached under the bottom plate 20, wherein the heat-generating electronic components of Zone III also correspond to the inlet 210a. In this prior art, when the working fluid flows downward to the lower cavity 21b from the inlet 210a, it flows to the two sides of cooling fins 22. In other words, it causes a diversion of the working fluid, which means the flow and flow rate of the zone IV on both sides are halved. Consequently, the heat exchange efficiency of the zone IV on both sides is reduced, and the heat dissipation efficiency is also poor. Consequently, even if the conventional liquid cooling device 2 is used, the heat-generating electronic components on both sides attached under the base plate 20 cannot effectively dissipate heat, so that it cannot achieve a uniform and effective heat dissipation effect.

Therefore, there is a need of providing a liquid cooling device to obviate the drawbacks encountered from the prior arts.

### SUMMARY OF THE INVENTION

It is an object of the present disclosure to provide a liquid cooling device with different ratios of inlet area and outlet area. Consequently, the flushing flow rate toward the cooling fins at the inlet is increased, so as to increase flow rate at the inlet and improve heat exchange efficiency.

It is another object of the present disclosure to provide liquid cooling device. The working fluid of the liquid cooling device is flushed downward and toward the cooling fins at the inlet, and then flows along the Z-axis, X-axis and Y-axis directions in sequence, and then returns along the X-axis and Y-axis direction. Consequently, the heat dissipation circulation path is significantly long, so that the heat exchange efficiency is increased, and the purpose of uniform heat dissipation is achieved.

In accordance with an aspect of the present disclosure, there is provided a liquid cooling device. The liquid cooling device includes a bottom plate, a cooling fin assembly, and a base. The cooling fin assembly is disposed on the bottom plate and includes a plurality of first cooling fins, a plurality of second cooling fins, and at least one third cooling fin. Each of the plurality of first cooling fins has a first front end, a first rear end, and a first top. The first top connects the first front end and the first rear end. Each of the plurality of second cooling fins has a second front end, a second rear end, and a second top. The second top connects the second front end and the second rear end. The at least one third cooling fin is disposed between the plurality of first cooling fins and the plurality of second cooling fins. The third cooling fin has a third front end, a third rear end, a third top, a first lateral side, and a second lateral side. The first lateral side and the second lateral side are arranged in the two opposite sides of the third top and both connect the third front end and the third rear end. The first lateral side faces the plurality of first cooling fins. The second lateral side faces the plurality of second cooling fins. The base covers on the cooling fin assembly and the bottom plate and has an inlet and an outlet. The inlet faces the fist top, and the outlet faces the second top.

In an embodiment, the base includes a liquid inlet recess and a liquid outlet recess, and the inlet is disposed in the liquid inlet recess, the outlet is disposed in the liquid outlet recess.

In an embodiment, the liquid inlet recess includes a guiding slope connected to the inlet.

In an embodiment, the guiding slope is a portion of a bottom surface of the liquid inlet recess.

In an embodiment, the liquid cooling device further includes a flow-limiting structure, which is arranged around the periphery of the inlet to block the inlet and the outlet.

In an embodiment, the plurality of first cooling fins has a first arrangement density, the plurality of second cooling fins has a second arrangement density, and the first arrangement density is greater than the second arrangement density.

In an embodiment, the plurality of first cooling fins has a first arrangement density, the plurality of second cooling fins has a second arrangement density, and the first arrangement density is the same as the second arrangement density.

In an embodiment, each of the first cooling fins, each of the second cooling fins and the third cooling fin of the cooling fin assembly are sheet metal structures with the same size.

In an embodiment, a thickness of the third cooling fin is greater than the thickness of each first cooling fin and the thickness of each second cooling fin.

In an embodiment, a height of the third cooling fin is greater than the height of each first cooling fin and the height of each second cooling fin.

In an embodiment, a length of the third cooling fin is greater than the length of each first cooling fin and the length of each second cooling fin.

In accordance with an aspect of the present disclosure, there is provided a liquid cooling device. The liquid cooling device includes a bottom plate, a cooling fin assembly, and a base. The cooling fin assembly is disposed on the bottom plate and includes a plurality of first cooling fins, a plurality of second cooling fins, and at least one third cooling fin. The at least one third cooling fin is disposed between the plurality of first cooling fins and the plurality of second cooling fins. The base covers on the cooling fin assembly and the bottom plate and has an inlet and an outlet. The inlet faces the fist top of the plurality of first cooling fins, and the outlet faces the second top of the plurality of second cooling fins. When a working fluid flows in from the inlet, it flows to the fist top of the plurality of first cooling fins along Z-axis, then flows to two ends of the plurality of first cooling fins along X-axis, and flows to two sides of the second cooling fins along Y-axis, finally flows to the outlet through the second cooling fins along X-axis and Y-axis directions, so as to form a three axial circulation path of Z-axis, X-axis and Y-axis directions.

The above contents of the present invention will become more readily apparent to those ordinarily skilled in the art after reviewing the following detailed description and accompanying drawings, in which:

### BRIEF DESCRIPTION OF THE DRAWINGS

FIG. 1A is a schematic cross-sectional view illustrating a liquid cooling device of the prior art;

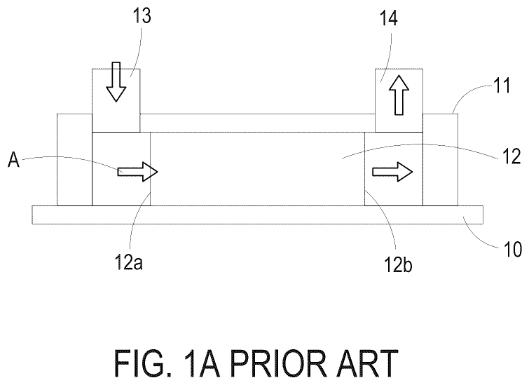

FIG. 1B is a top view illustrating a flowing sequence of a working fluid in the liquid cooling device of FIG. 1A;

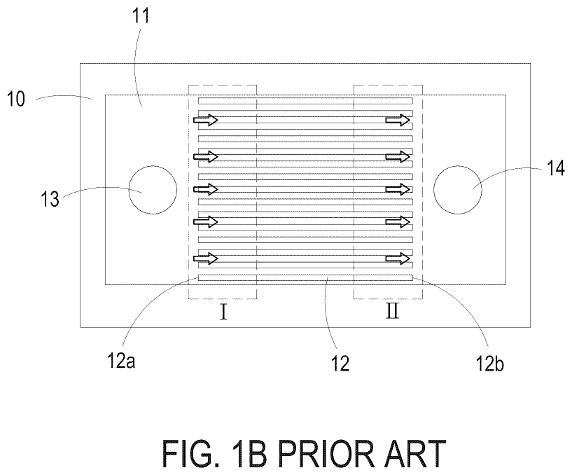

FIG. 2A is a schematic cross-sectional view illustrating another liquid cooling device of the prior art;

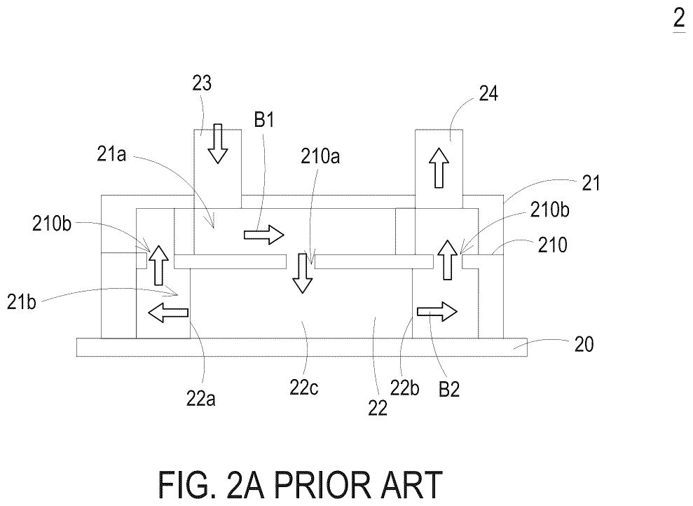

FIG. 2B is a top view illustrating a flowing sequence of a working fluid in the liquid cooling device of FIG. 2A;

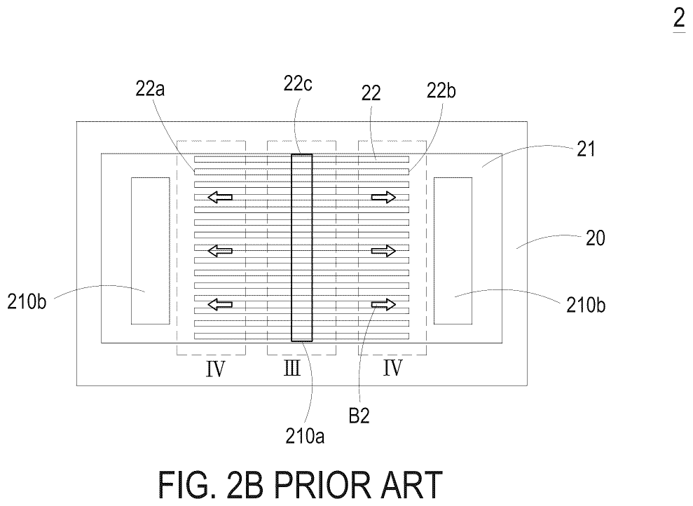

FIG. 3A is a schematic exploded view illustrating a liquid cooling device according to a first embodiment of the present disclosure;

FIG. 3B is a schematic bottom view illustrating a base of the liquid cooling device of FIG. 3A;

FIG. 3C is a schematic perspective view illustrating a cooling fin assembly and a bottom plate of the liquid cooling device of FIG. 3A;

FIG. 3D is a schematic perspective view illustrating a flowing sequence of a working fluid in the liquid cooling device of FIG. 3A;

FIG. 3E is a top view illustrating the flowing sequence of the working fluid in the liquid cooling device of FIG. 3A;

FIG. 4 is a top view illustrating a flowing sequence of a working fluid in the liquid cooling device according to a second embodiment of the present disclosure; and

FIG. 5 is a top view illustrating a flowing sequence of a working fluid in the liquid cooling device according to a third embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. For example, if the following content of the present disclosure describes arranging a first feature on or above a second feature, it means that it includes an embodiment in which the first feature and the second feature are arranged in direct contact. Meanwhile, it also includes another embodiment in which an additional feature may be disposed between the first feature and the second feature, namely, the first features and the second features may not be in direct contact. Further, spatially relative terms, such as “above” “under” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first assembly could be termed a second assembly, and, similarly, a second assembly could be termed a first assembly, without departing from the scope of example embodiments. Besides, “and/or” and the like may be used herein for including any or all combinations of one or more of the associated listed items.

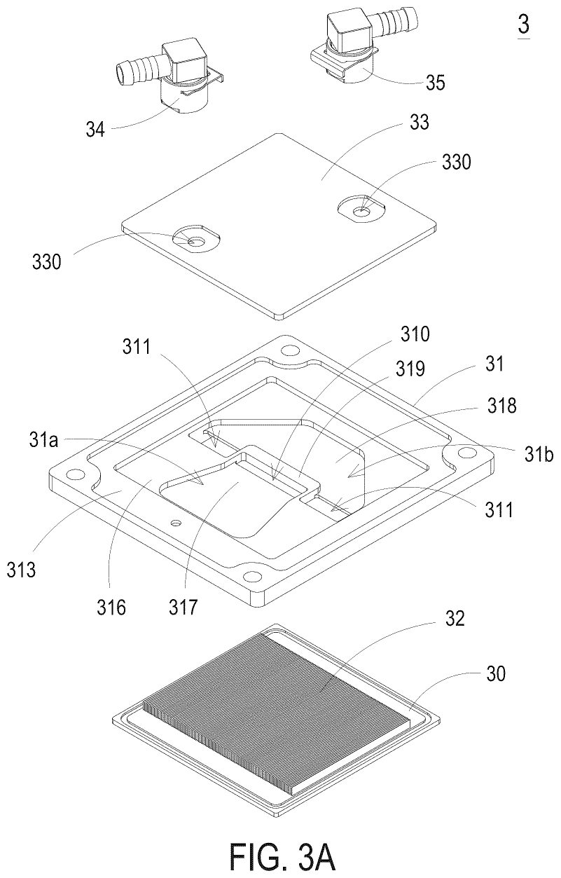

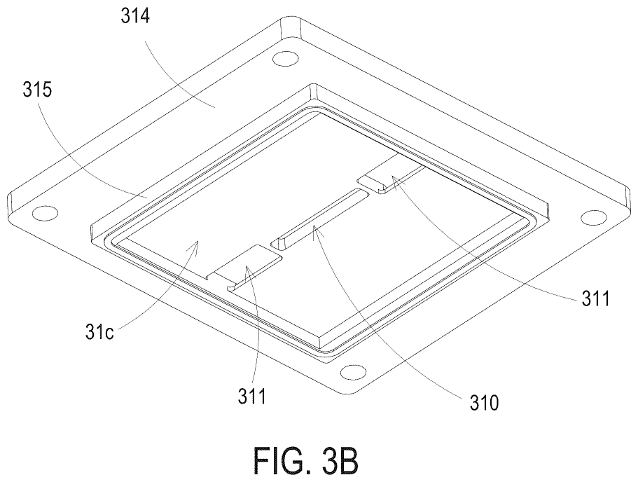

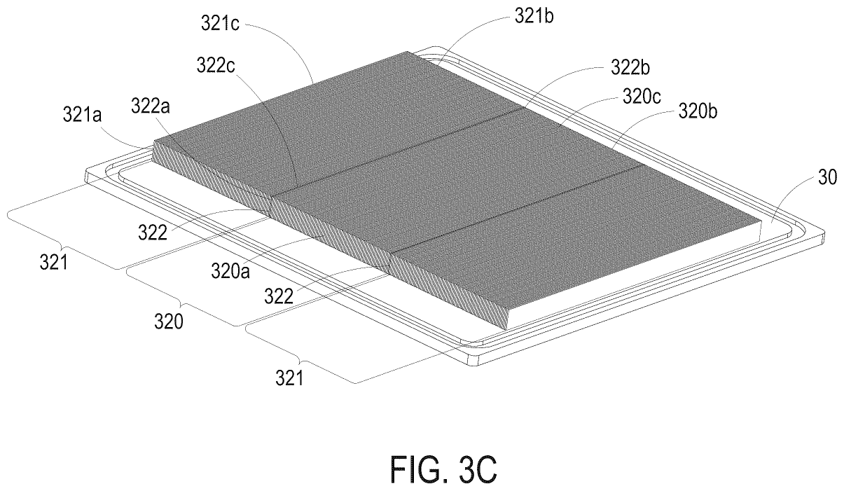

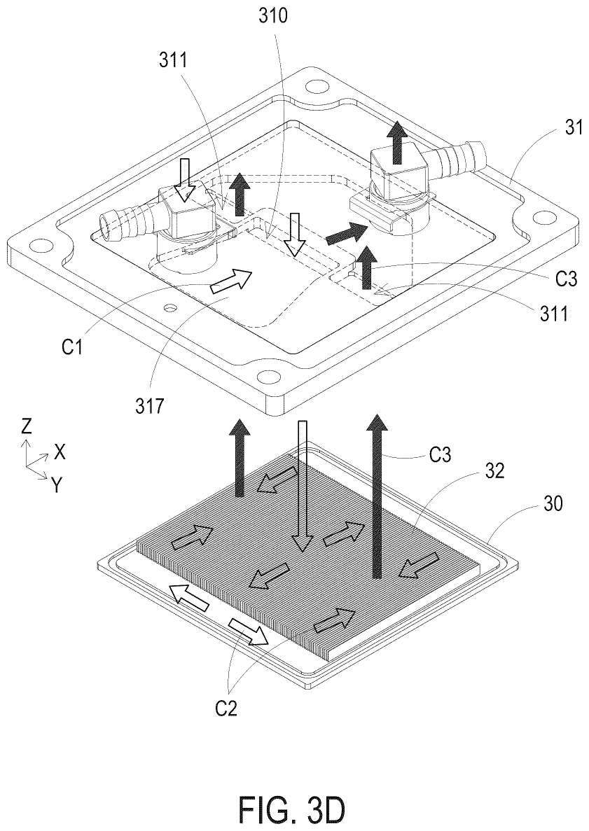

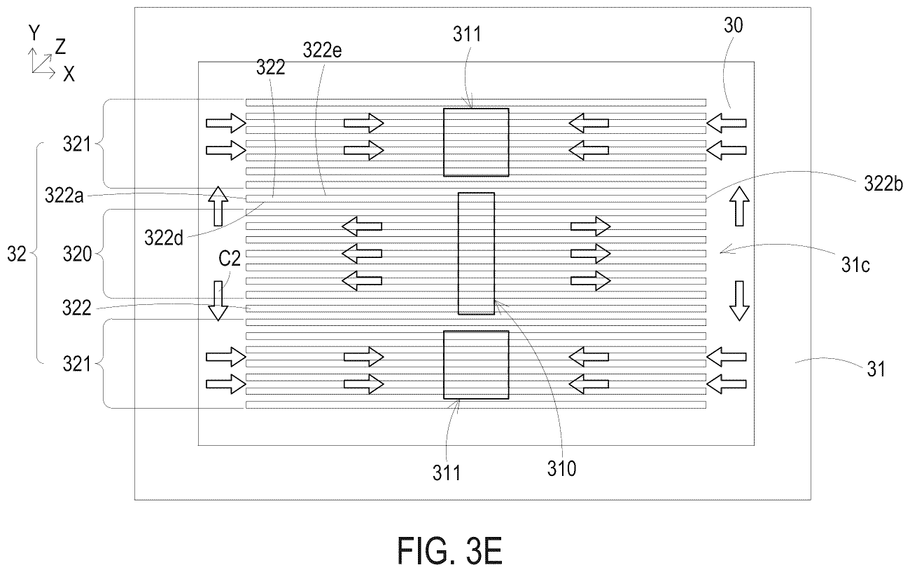

Please refer to FIG. 3A, FIG. 3B and FIG. 3C. FIG. 3A is a schematic exploded view illustrating a liquid cooling device according to a first embodiment of the present disclosure. FIG. 3B is a schematic bottom view illustrating a base of the liquid cooling device of FIG. 3A. FIG. 3C is a schematic perspective view illustrating a cooling fin assembly and a bottom plate of the liquid cooling device of FIG. 3A. As shown in FIG. 3A and FIG. 3C, in the embodiment, the liquid cooling device 30 comprise a bottom plate 30, a base 31, and a cooling fin assembly 32. The cooling fin assembly 32 is disposed on the bottom plate 30, and includes a plurality of first cooling fins 320, a plurality of second cooling fins 321, and a third cooling fin 322. In the embodiment, each of the plurality of first cooling fins 320 has a first front end 320a, a first rear end 320b, and a first top 320c, the first top 320c connects the first front end 320a and the first rear end 320b. Similar, each of the plurality of second cooling fins 321 has a second front end 321a, a second rear end 321b, and a second top 321c, the second top 321c connects the second front end 321a and the second rear end 321b. The at least one third cooling fin 322 is disposed between the plurality of first cooling fins 320 and the plurality of second cooling fins 321. The third cooling fin 322 has a third front end 322a, a third rear end 322b, a third top 322c, a first lateral side 322d, and a second lateral side 322e. The first lateral side 322d and the second lateral side 322e are arranged in the two opposite sides of the third top 322c and both connect the third front end 322a and the third rear end 322b, and the first lateral side 322d faces the plurality of first cooling fins 321, the second lateral side 322e faces the plurality of second cooling fins 322. The base 31 covers on the cooling fin assembly 32 and the bottom plate 30, and has an inlet 310 and an outlet 311. In this embodiment, the inlet 310 faces the first top 320c, and the outlet 311 faces the second top 321c.

As shown in FIG. 3A and FIG. 3B. In the embodiment, the base 31 of the liquid cooling device 3 is a plate structure with a specific thickness. The base 31 comprises a first surface 313 and a second surface 314 (as shown in FIG. 3B). As shown in FIG. 3A, the first surface 313 is partially recessed to form a square recess 316, but not limited thereto. In this embodiment, the inlet 310 is a slender opening, which is disposed in the center of the square recess 316 and penetrates the base 31, wherein the type and the position of the inlet 310 can be adjustable according the practical requirement, and not limited thereto. Moreover, in the embodiment, the bottom surface of the square recess 316 are recessed to form two separate recesses, which are the liquid inlet recess 31a and the liquid outlet recess 31b. In some embodiments, the bottom surface 317 can be but not limited to be an inclined surface as a guiding slope for guiding the working fluid to flow to the inlet 310, and reduce the liquid pressure. As shown in FIG. 3A, the bottom surface 317 as the guiding slope of the liquid inlet recess 31a connects to the inlet 310. In other embodiments, the guiding slope may be a portion of the bottom surface 317 of the liquid inlet recess 31a, but not limited thereto. In the embodiment, the base 31 of the liquid cooling device 3 comprises two outlets 311. The two outlets 311 are rectangular openings, which both penetrate the base 31 and respectively disposed on the two sides of the inlet 310. The two outlets 311 are disposed within the liquid outlet recess 31b of the square recess 316, and both connect the bottom surface 318 of the liquid outlet recess 31b. The number, types and positions of the outlet 311 can be adjustable according the practical requirement, and not limited thereto. In this embodiment, the liquid cooling device 3 further includes a flow-limiting structure 319, which is disposed in the square recess 316 of the base 31. As shown in FIG. 3A, the flow-limiting structure 319 can be but not limited to be a frame structure, and is arranged around the periphery of the inlet 310, so as to block the inlet 310 and the two outlets 311 of the liquid outlet recess 31b. In this circumstance, the working fluid can be limited only to flow into the below cavity 31c through the inlet 310, but cannot escape to the adjacent outlets 311. In addition, as shown in FIG. 3B, a frame 315 is protruded on the second surface 314, wherein the appearance of the frame 315 corresponds to the bottom plate 30. Namely, when the base 31 covers on the cooling fin assembly 32 and the bottom plate 30, the frame 315 covers on the bottom plate 30, and a cavity 31c is defined by the frame 315 and the bottom plate 30. In the embodiment, the cooling fin assembly 32 is disposed within the cavity 31c.

Please refer to FIG. 3A and FIG. 3D. FIG. 3D is a schematic perspective view illustrating a flowing sequence of a working fluid in the liquid cooling device of FIG. 3A. In the embodiment, the liquid cooling device 3 further includes a cover 33, but not limited thereto. The cover 33 correspondingly covers on the square recess 316 of the base 31. There are two openings 330 penetrating the cover 33, which are respectively communicating with an inlet tube 34 and an outlet tube 35. Consequently, when the cover 33 covers on the base 31, the working fluid flows in from the inlet tube 34, passes through the openings 330 of the cover 33, and is transmitted downward to the liquid inlet recess 31a of the square recess 316 of the base 31, as shown in the direction indicated by the white arrows C1 of FIG. 3D. Moreover, the working fluid is guided along the bottom surface 317 (also the guiding slope) to the inlet 310, and is then transmitted downward to the cavity 31c. Consequently, the working fluid flows within the cavity 31c and conducts heat exchange with the cooling fin assembly 32. As shown in FIG. 3D, when a working fluid is transmitted downward to the cavity 31c, it is injected vertically downward to the cooling fin assembly 32 along Z-axis, and then flows to the two ends of the cooling fin assembly 32 along X-axis, as shown in the direction indicated by the white arrows C2. After the working fluid flows to the two ends of the cooling fin assembly 32, it flows to the two sides horizontally along Y-axis, and then returns to the center of the cooling fin assembly 32 along X-axis from the two sides. Finally, the working fluid flows upward to the two outlets 311 along Z-axis, as shown in the direction indicated by the black arrows C3, so as to flow to the liquid outlet recess 31b, and then transmit to the outlet tube 35 through the opening 330 of the cover 33. Consequently, the heat dissipation circulation path of the working fluid is formed. Besides, in the embodiment, the inlet 310 is correspondingly disposed between the two outlets 311. In some embodiments, the area ratios of the inlet 310 and the sum of the two outlets is 1:2, but not limited thereto. Notably, by the design of slender opening and small area of the inlet 310, the downward flushing pressure of the working fluid is increased, so that the flow rate of the inlet 310 is also increased. Consequently, the working fluid performs the heat dissipation circulation path in the liquid cooling device 3 can maintain a high flow rate.

Please refer to Table 1 below, which is a flow rate comparison table between the embodiment and the two prior art.

TABLE 1

| | Liquid cooling | Liquid cooling | Liquid cooling |
|---|---|---|---|
| | device 1 of | device 2 of | device 3 of the |
| | Prior Art | Prior Art | embodiment |
| Total flow | Q | Q | Q |
| Flow rate of inlet | V | 1/2 V | 1.5 V |
| Flow rate of outlet | V | 1/2 V | 0.75 V |

From the above Table 1, the liquid cooling device 3 of this embodiment is designed with a relatively small area of the inlet 310, so that when the working fluid is injected into the cavity 31c, it limits the flow and only flushes a portion of cooling fin assembly 32. Consequently, the flow rate of the inlet 310 of the embodiment is increased to 1.5 times that of the liquid cooling device 1 of the prior art, and is increased to 3 times that of the liquid cooling device 2 of the prior art. According to this manner, the flow rate of the liquid cooling device 3 is increased, the heat exchange amount is increased, and the hottest heat-generating electronic components under the bottom plate 30 can be prioritized for heat dissipation. As for the heat-generating electronic components on both sides and other areas, due to the aforementioned flow restriction factor at the inlet 310, the flow rate is still increased compared to the prior arts, so that better heat exchange efficiency can be maintained, and heat-generating electronic components in other areas can also achieve good heat dissipation efficiency, thereby dissipating heat evenly.

Please refer to FIG. 3E. FIG. 3E is a top view illustrating the flowing sequence of the working fluid in the liquid cooling device of FIG. 3A. As shown in FIG. 3E, the cooling fin assembly 32 comprises a plurality of first cooling fins 320, a plurality of second cooling fins 321, and at least one third cooling fin 322. In the embodiment, the cooling fin assembly 32 has one group of first cooling fins 320, two groups of second cooling fins 321, and two third cooling fins 322. Each group of the first cooling fins and the second cooling fins includes a plurality of first cooling fins 320 and a plurality of second cooling fins 321, respectively. In the embodiment, the plurality of first cooling fins 320, the plurality of second cooling fins 321, and the third cooling fin 322 can be made of metal materials with high thermal conductivity, but not limited thereto. In some embodiments, the plurality of first cooling fins 320, the plurality of second cooling fins 321, and the third cooling fin 322 can be the same sheet metal structure, such as the same appearance or the same size, but not limited thereto. In other embodiments, the length of the third cooling fin 322 is greater than the length of the first cooling fins 320 and the length of the second cooling fins 321, or the thickness of the third cooling fin 322 is greater than the length of the first cooling fins 320 and the length of the second cooling fins 321, or the height of the third cooling fin 322 is greater than the height of the first cooling fins 320 and the height of the second cooling fins 321. However, the length, the thickness, and the height of third cooling fin 322 can be adjustable according the practical requirement, and not limited thereto. As shown in FIG. 3E, in the embodiment, the one group of the first cooling fins 320 is correspondingly arranged under the inlet 310, and the two groups of the second cooling fins 321 are respectively arranged under the two outlet 311. The two third cooling fins 322 are respectively arranged between groups of the first cooling fins 320 and the second cooling fins 321. In other words, the group of the first cooling fins 320 is sandwiched between the two groups of the second cooling fins 321 through the two third cooling fins 322. As aforementioned, each of the first cooling fins 320 has a first front end 320a, a first rear end 320b, and a first top 320c, and the first top 320c connects the first front end 320a and the first rear end 320b. Similarly, each of the second cooling fins 321 has a second front end 321a, a second rear end 321b, and a second top 321c, and the second top 3201 connects the second front end 321a and the second rear end 321b. Each of the third cooling fins 322 also has a third front end 322a, a third rear end 322b, a third top 322c, a first lateral side 322d, and a second lateral side 322e, wherein the first lateral side 322d and the second lateral side 322e are respectively disposed on the two side of the third top 322c, and both connect the third front end 321a and the third rear end 321b at the same time. In the embodiment, the first lateral side 322d faces the plurality of first cooling fins 320, and the second lateral side 322d faces the plurality of second cooling fins 321. As shown in FIG. 3E, the inlet 310 is arranged above the plurality of first cooling fins 320, in other words, the inlet 310 faces the first top 320c of the plurality of first cooling fins 320. Similarly, the two outlets respectively face the second top 321c of the two groups of the second cooling fins 321. In the embodiment, when the working fluid flows downward to the cavity 31c along Z-axis from the inlet 310, it first touches the first tops 320c of the first cooling fins 320, and then flows to the two ends, that is the first front ends 320a and the first rear ends 320b, along X-axis. After that, as shown in the allows C2, the working fluid continuously flows to the two sides of the bottom plate 30 and the cavity 31c alone Y-axis, which passes through the third front ends 322a, the third rear ends 322d of the third cooling fins 322 to the second frond ends 321a, the second rear ends 321b of the two group of the second cooling fins 321. Meanwhile, in response to the pressure of the working fluid drawn outward, it reflows toward the center of the second cooling fins 321 along X-axis, and then flows out of the outlet 311 upward along Z-axis. Since the working fluid flows toward the two sides of the cavity 31c along Y-axis, it has a longer heat dissipation circulation path than the prior art. Consequently, it has better heat dissipation ability and can achieve the purpose of even heat dissipation.

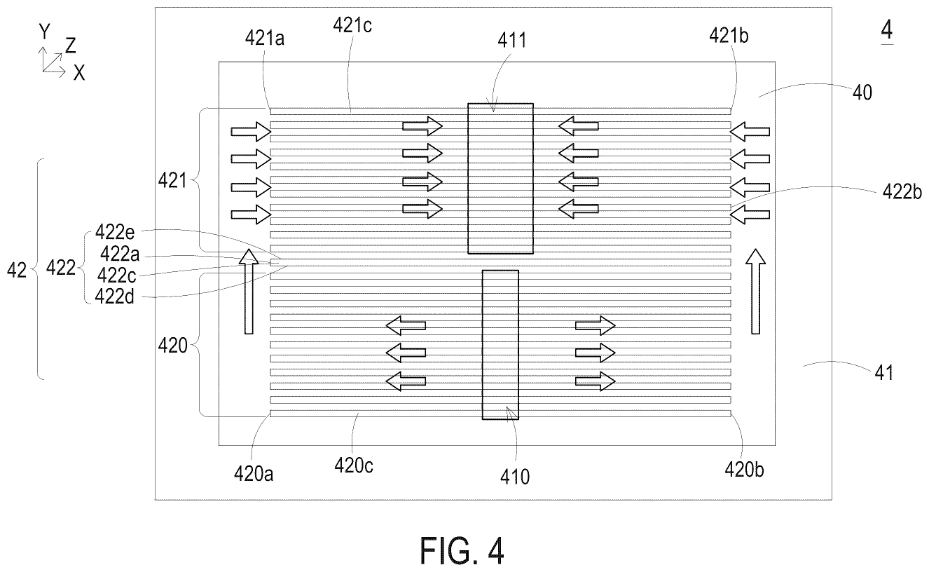

Please refer to FIG. 4. FIG. 4 is a top view illustrating a flowing sequence of a working fluid in the liquid cooling device according to a second embodiment of the present disclosure. As shown in FIG. 4, in this embodiment, the liquid cooling device 4 also comprises a bottom plate 40, a base 41, and a cooling fin assembly 42. The cooling fin assembly 42 is disposed on the bottom plate 40 and comprises a plurality of first cooling fins 420, a plurality of second cooling fins 421, and at least one third cooling fin 422. Similarly, each of the first cooling fins 420 has a first front end 420a, a first rear end 420b, and a first top 420c, and the first top 420c connects the first front end 420a and the first rear end 420b. Each of the second cooling fins 421 has a second front end 421a, a second rear end 421b, and a second top 421c, and the second top 421 connects the second front end 421a and the second rear end 421b. As shown in FIG. 4, in this embodiment, the liquid cooling device 4 only has one third cooling fin 422, and it is arranged between the plurality of first cooling fins 420 and the plurality of second cooling fins 421 for separating the first cooling fins 420 and the second cooling fins 421. In this embodiment, the third cooling fin 422 also has a third front end 422a, a third rear end 422b, a third top 422c, a first lateral side 422d, and a second lateral side 422e, wherein the first lateral side 422d and the second lateral side 422e are respectively disposed on the two side of the third top 422c, and both connect the third front end 421a and the third rear end 421b at the same time. In the embodiment, the first lateral side 422d faces the plurality of first cooling fins 420, and the second lateral side 422d faces the plurality of second cooling fins 421. The base 41 covers on the cooling fin assembly 42 and the base 40, and has an inlet 410 and outlet 411, the inlet 410 faces the first top 420c, and the outlet 411 faces the second top 421c. While in this embodiment, the difference between this embodiment and the previous embodiment is that there is only one outlet 411, and there is only one group of second cooling fins 421 corresponding to the single outlet 411. In this embodiment, the inlet 410 is arranged above the heat-generating electronic components with the highest heat source. As shown in FIG. 4, when the working fluid flows downward from the inlet 410, due to the direction is vertically downward along Z-axis, it first touches the first tops 420c of the first cooling fins 420, and then flows to the two ends of the first cooling fins 420, that is the first front ends 420a and the first rear ends 420b, along X-axis, so that the hottest heat-generating electronic components below the first cooling fins 420 can be heat dissipated first. After that, the working fluid continuously flows to the two sides of the bottom plate 40 alone Y-axis, which passes through the third front end 422a, the third rear end 422d of the third cooling fin 422 to the second frond ends 421a, the second rear ends 421b of the second cooling fins 421. Meanwhile, in response to the pressure of the working fluid drawn outward, it reflows toward the outlet 411 arranged corresponding to the center of the second cooling fins 421 along X-axis and Y-axis directions. In this embodiment, the working fluid includes the three axial heat dissipation circulation path in Z-axis, X-axis, and Y-axis directions. Consequently, the heat dissipation circulation path is significantly longer than that of the prior art, so that the heat dissipation capability is better and can achieve the purpose of uniform heat dissipation.

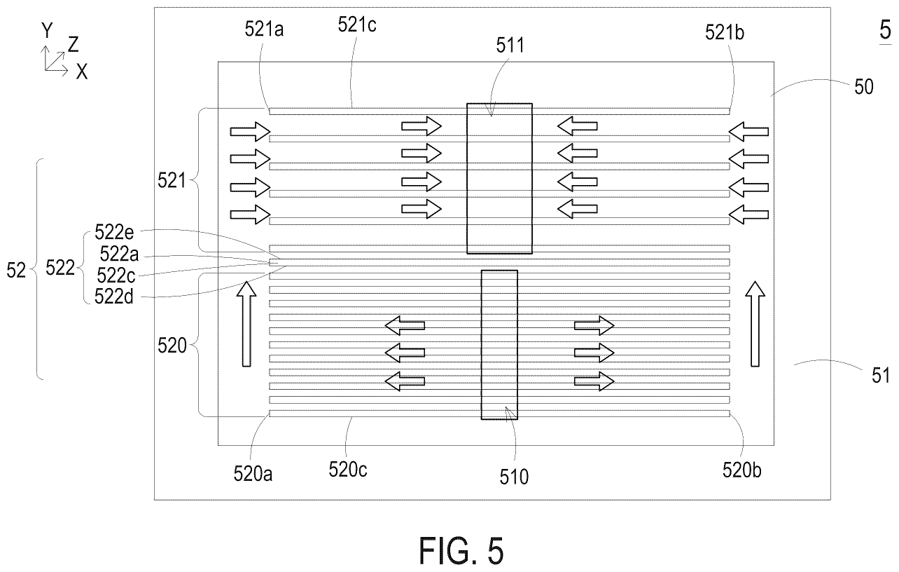

Please refer to FIG. 5. FIG. 5 is a top view illustrating a flowing sequence of a working fluid in the liquid cooling device according to a third embodiment of the present disclosure. As shown in FIG. 5, in this embodiment, the liquid cooling device 5 also comprises a bottom plate 50, a base 51, and a cooling fin assembly 52. The cooling fin assembly 52 is disposed on the bottom plate 50 and comprises a plurality of first cooling fins 520, a plurality of second cooling fins 521, and at least one third cooling fin 522. Similar with the previous embodiment, each of the first cooling fins 520 has a first front end 520a, a first rear end 520b, and a first top 520c. Each of the second cooling fins 521 has a second front end 521a, a second rear end 521b, and a second top 521c. The third cooling fin 522 is arranged between the plurality of first cooling fins 520 and the plurality of second cooling fins 521, and also has a third front end 522a, a third rear end 522b, a third top 522c, a first lateral side 522d, and a second lateral side 522e, wherein the first lateral side 522d faces the plurality of first cooling fins 520, and the second lateral side 522d faces the plurality of second cooling fins 521. Moreover, in the embodiment, the base 51 also has single inlet 510 and single outlet 511, the single inlet 510 faces the first top 520c, and the single outlet 511 faces the second top 521c. While in this embodiment, the plurality of first cooling fins 520 has a first arrangement density, the plurality of second cooling fins 521 has a second arrangement density, and the first arrangement density is greater than the second arrangement density. In other words, the number of the first cooling fins 520 is more than that of the second cooling fins 521, that is, the first cooling fins 520 has dense first arrangement density, and the second cooling fins 521 has sparse second arrangement density. Namely, the distance between each second cooling fin 521 is large, through these different density arrangements, the pressure drop of the overall liquid cooling device 5 is improved. Alternatively, in some embodiments, the first arrangement density of the first cooling fins 520 is equal to or less than the second arrangement density of the second cooling fins 521, but not limited thereto. The numbers, the arrangement density, and the arrangements of the first cooling fins 520 and the second cooling fins 521 can be adjustable according the arrangement of the heat-generating electronic components of different heat source or according the practical requirement, and not limited thereto.

As shown in FIG. 5, when the working fluid flows vertically downward from the inlet 510 of the liquid cooling device 5 along Z-axis, it first touches the first tops 520c of the first cooling fins 520, and then flows toward to the first front ends 520a and the first rear ends 520b of the first cooling fins 520. After that, the working fluid continuously flows to the two sides of the bottom plate 50 alone Y-axis, which passes through the third front end 522a, the third rear end 522d of the third cooling fin 522 to the second frond ends 521a, the second rear ends 521b of the second cooling fins 521 with sparse second arrangement density. Meanwhile, in response to the pressure of the working fluid drawn outward, it reflows toward the outlet 511 arranged corresponding to the center of the second cooling fins 521 along X-axis and the Y-axis directions. Consequently, the heat dissipation circulation path is longer, and the heat dissipation efficiency is enhanced and the purpose of uniform heat dissipation is also achieved in cooperate with the first cooling fins 520 and the second cooling fins 521.

From the above descriptions, the present disclosure provides a liquid cooling device. The liquid cooling device has different ratios of inlet area and outlet area, so that the flushing flow rate toward the cooling fins at the inlet is increased, the flow rate at the inlet is increased and heat exchange efficiency is also improved. Moreover, the working fluid of the liquid cooling device is flushed downward and toward the cooling fins at the inlet, and then flows along the Z-axis, X-axis and Y-axis directions in sequence, and then returns along the X-axis and Y-axis direction. Consequently, the heat dissipation circulation path is significantly long, so that the heat exchange efficiency is increased, and the purpose of uniform heat dissipation is achieved.

While the disclosure has been described in terms of what is presently considered to be the most practical and preferred embodiments, it is to be understood that the disclosure needs not be limited to the disclosed embodiment.

What is claimed is:

1. A liquid cooling device, comprising:
a bottom plate;
a cooling fin assembly disposed on the bottom plate, comprising:
a plurality of first cooling fins, wherein each of the plurality of first cooling fins has a first front end, a first rear end, and a first top, the first top connects the first front end and the first rear end;
a plurality of second cooling fins, wherein each of the plurality of second cooling fins has a second front end, a second rear end, and a second top, the second top connects the second front end and the second rear end; and
at least one third cooling fin disposed between the plurality of first cooling fins and the plurality of second cooling fins, wherein the third cooling fin has a third front end, a third rear end, a third top, a first lateral side, and a second lateral side, and the first lateral side and the second lateral side are arranged in two opposite sides of the third top and both connect the third front end and the third rear end, and the first lateral side faces the plurality of first cooling fins, the second lateral side faces the plurality of second cooling fins; and
a base covering on the cooling fin assembly and the bottom plate, and having an inlet and an outlet, wherein the inlet faces the fist top, and the outlet faces the second top.

2. The liquid cooling device according to claim 1, wherein the base comprises a liquid inlet recess and a liquid outlet recess, and the inlet is disposed in the liquid inlet recess, the outlet is disposed in the liquid outlet recess.

3. The liquid cooling device according to claim 2, wherein the liquid inlet recess comprises a guiding slope connected to the inlet.

4. The liquid cooling device according to claim 3, wherein the guiding slope is a portion of a bottom surface of the liquid inlet recess.

5. The liquid cooling device according to claim 1, wherein the liquid cooling device further comprises a flow-limiting structure, which is arranged around the periphery of the inlet to block the inlet and the outlet.

6. The liquid cooling device according to claim 1, wherein the plurality of first cooling fins has a first arrangement density, the plurality of second cooling fins has a second arrangement density, and the first arrangement density is greater than the second arrangement density.

7. The liquid cooling device according to claim 1, wherein the plurality of first cooling fins has a first arrangement density, the plurality of second cooling fins has a second arrangement density, and the first arrangement density is the same as the second arrangement density.

8. The liquid cooling device according to claim 1, wherein each of the first cooling fins, each of the second cooling fins and the third cooling fin of the cooling fin assembly are sheet metal structures with the same size.

9. The liquid cooling device according to claim 1, wherein a thickness of the third cooling fin is greater than the thickness of each first cooling fin and the thickness of each second cooling fin.

10. The liquid cooling device according to claim 1, wherein a height of the third cooling fin is greater than the height of each first cooling fin and the height of each second cooling fin.

11. The liquid cooling device according to claim 1, wherein a length of the third cooling fin is greater than the length of each first cooling fin and the length of each second cooling fin.

12. A liquid cooling device, comprising:
a bottom plate;
a cooling fin assembly disposed on the bottom plate, comprising:
a plurality of first cooling fins;
a plurality of second cooling fins; and
at least one third cooling fin disposed between the plurality of first cooling fins and the plurality of second cooling fins; and
a base covering on the cooling fin assembly and the bottom plate, and having an inlet and an outlet, wherein the inlet faces a fist top of the plurality of first cooling fins, and the outlet faces a second top of the plurality of second cooling fins,
wherein when a working fluid flows in from the inlet, it flows to the fist top of the plurality of first cooling fins along a Z-axis direction, then flows to two ends of the plurality of first cooling fins along a X-axis direction, and flows to two sides of the second cooling fins along a Y-axis direction, finally flows to the outlet through the second cooling fins along the X-axis direction and the Y-axis direction, so as to form a three axial circulation path of the Z-axis direction, the X-axis direction and the Y-axis direction.

13. The liquid cooling device according to claim 12, wherein the liquid cooling device further comprises a flow-limiting structure, which is arranged around the periphery of the inlet to block the inlet and the outlet.

14. The liquid cooling device according to claim 12, wherein the plurality of first cooling fins has a first arrangement density, the plurality of second cooling fins has a second arrangement density, and the first arrangement density is greater than the second arrangement density.

15. The liquid cooling device according to claim 12, wherein each of the first cooling fins, each of the second cooling fins and the third cooling fin of the cooling fin assembly are sheet metal structures with the same size.
